(19) United States
(12) Patent Application Publication
(10) Pub. No.: US 2009/0084445 A1
(43) Pub. Date: Apr. 2, 2009

(54) Nanojet Spouting Method and Nanojet Mechanism

(75) Inventors: Yutaka Maniwa, Sagamihara-shi (JP); Hiromichi Kataura, Tsukuba-shi (JP)

Correspondence Address: OLIFF & BERRIDGE, PLC, P.O. BOX 320850, ALEXANDRIA, VA, 22320-4850, US

(73) Assignees: Japan Science and Technology Agency, Kaisaguchi-shi (JP); National Institute of Advanced Industrial Science and Technology, Tokyo (JP)

(21) Appl. No.: 11/630,897

(22) PCT Filed: Jun. 27, 2005
(86) PCT No.: PCT/JP05/11730

§ 371 Date: Dec. 29, 2007

(30) Foreign Application Priority Data
Jun. 30, 2004 (JP) 2004-193634

(51) Int. Cl. B82B 1/00; B81B 7/02; B41J 2/04

(52) U.S. Cl. 137/2; 137/828; 347/56; 977/742; 977/902

(57) ABSTRACT

A liquid is occluded in a predetermined carbon nanotube and then heated above a liquid-gas phase transition temperature to spout from the carbon nanotube.

### TECHNICAL FIELD

This invention relates to a nanojet spouting method and a nanojet mechanism.

### BACKGROUND ART

Water confined in a limited domain is expected to express unique characteristics which cannot be observed in the water of a bulk condition. The water of such a state actually exists in common environment and in vivo, but its physical characteristics are known little. Because, a wall confining type container is not sufficiently developed and also the above-mentioned water confined in the limited domain has not been studied sufficiently in some senses.

### DISCLOSURE OF THE INVENTION

### Problems to be Solved by the Invention

It is an object of the invention to obtain a structural body having novel characteristics by using a carbon nanotube having a high purity and a single wall face as a wall confining type container and rendering a liquid such as water or the like to be occluded and confined in the carbon nanotube.

### Means for Solving Problems

In order to achieve the above object, the invention is concerned with a nanojet spouting method characterized by comprising the steps of:
providing a predetermined carbon nanotube;
occluding a liquid in the carbon nanotube; and
heating the liquid above a liquid-gas phase transition temperature to spout the liquid from the carbon nanotube.

Also, the invention is concerned with a nanojet mechanism characterized by comprising:

a predetermined carbon nanotube; and

a liquid to be occluded in the carbon nanotube and to be spouted from the carbon nanotube by heating above a liquid-gas phase transition temperature.

The inventors have provided a predetermined carbon nanotube and tried to use the carbon nanotube as a wall confining type container and occlude and support water in the carbon nanotube. As a result, the inventors have discovered that the water can be supported at an atomic level in the carbon nanotube at a temperature of not lower than room temperature under ambient pressure without conducting operations such as pressurizing, cooling and the like by setting a diameter of the carbon nanotube within a certain range. Consequently, the inventors have succeeded to obtain a novel structural body of water, i.e. an ice nanotube occluded and supported at the atomic level in the carbon nanotube.

On the other hand, in order to keep the ice nanotube in the carbon nanotube, it is necessary to hold the ice nanotube at a temperature below the liquid-gas phase transition temperature. Since a width of the phase transition temperature is as very narrow as about 5 K, however, the inventors have discovered that when the ice nanotube is heated above the phase transition temperature, the ice nanotube suddenly becomes steam to be spouted from the carbon nanotube.

As seen from the above-mentioned content, the “ice nanotube” means a novel structural body of water occluded and kept inside the carbon nanotube at the atomic level. Also, the ice nanotube is mainly kept in the cavity of the carbon nanotube.

Furthermore, the above-mentioned phenomenon is confirmed in alcohols such as ethyl alcohol and the like in addition to the water. Therefore, the above-mentioned nanojet mechanism and the nanojet spouting method can be used as an ink jet by incorporating a given pigment or the like into the above-mentioned liquid such as the water or the like, but also can be used as a jet mechanism or the like actuating nano-size parts by utilizing a counteraction produced during the spouting.

Moreover, in a preferable embodiment of the invention, plural carbon nanotubes are provided and bundled to form a carbon nanotube bundle, and plural liquids are occluded in the carbon nanotube bundle and a light corresponding to an absorption wavelength of a predetermined liquid is irradiated. In this case, only the predetermined liquid can be spouted from the carbon nanotube by heating above its liquid-gas phase transition temperature.

In another preferable embodiment of the invention, the plural carbon nanotubes having different structures and sizes are provided and bundled to form a carbon nanotube bundle, and plural liquids are occluded in the carbon nanotube bundle, and only a predetermined liquid can be spouted from the carbon nanotube by heating above its liquid-gas phase transition temperature based on the difference of absorption wavelengths resulted from the structures and sizes of the carbon nanotubes constituting the carbon nanotube bundle.

Moreover, although the liquid occluded in the carbon nanotube is spouted in the invention, its spouting behavior is not particularly limited. For example, the liquid can be spouted as a fine drop in the form of spray and also spouted as a steam. However, since the liquid is heated above its liquid-gas phase transition temperature as regards the spouting, it is commonly vaporized and spouted.

### EFFECTS OF THE INVENTION

As described above, according to the invention, there can be obtained a novel structural body as the nanojet mechanism by using the carbon nanotube and rendering the liquid such as water or the like to be occluded and confined in the carbon nanotube, and there can be provided a novel method referred to as the nanojet spouting method based on such a mechanism.

### BRIEF DESCRIPTION OF THE DRAWINGS

FIG. 1 is a model diagram showing an example of the ice nanotube used in the nanojet mechanism and the nanojet spouting method according to the invention;

FIG. 2 is a schematic view showing an example of the nanotube mechanism according to the invention;

FIG. 3 is a schematic view showing another example of the nanotube mechanism according to the invention; and

FIG. 4 is an XRD pattern of a carbon nanotube bundle used in the nanojet mechanism and the nanojet spouting method according to the invention.

### BEST MODE FOR CARRYING OUT THE INVENTION

Details and other features and merits of the invention will be described in detail based on the best mode.

In the invention, there is first provided a carbon nanotube for occluding a target liquid. The carbon nanotube is not particularly limited in its size as far as it can occlude and keep the liquid. However, as the diameter of the carbon nanotube becomes large, an environmental temperature for keeping the liquid, i.e. a liquid-gas phase transition temperature lowers, while as the diameter of the carbon nanotube becomes small, the environmental temperature for keeping the liquid, i.e. the liquid-gas phase transition temperature tends to be raised. Therefore, the environmental temperature can be set within a desired range by properly controlling the diameter of the carbon nanotube.

Concretely, when the diameter of the carbon nanotube is not more than 3.0 nm, the environmental temperature, i.e., the liquid-gas phase transition temperature can be made not lower than room temperature. Moreover, the lower limit of the diameter of the carbon nanotube is 0.7 nm considering an actual production method of the carbon nanotube or the like.

Also, as the carbon nanotube can be used optional ones as far as they satisfy the above requirement, without distinguishing between a monolayer and a multilayer.

Moreover, the liquid-gas phase transition temperature is preferable to be not less than 0° C. In this case, the phase transition temperature is set within a temperature range in the neighborhood of room temperature, so that the above-mentioned nanojet mechanism can be simply attained by slightly heating or cooling. The above-mentioned range of the phase transition temperature can be accomplished by controlling the diameter of the carbon nanotube.

As a means for heating the carbon nanotube can be used a heater heating using an usual heater and means such as a light irradiation from a light source having an absorption wavelength region of the liquid occluded in the carbon nanotube and the like.

Moreover, the carbon nanotubes may be used alone or used as a carbon nanotube bundle formed by bundling plural ones. In the latter case, plural liquids can be occluded in the bundle as a whole. Among the plural liquids, only a predetermined liquid can be heated above the liquid-gas phase transition temperature of the predetermined liquid and spouted from the carbon nanotube keeping the predetermined liquid by irradiating a light corresponding to an absorption wavelength of the predetermined liquid.

Therefore, when the plural liquids contain, for example, different pigments with each other, only the liquid containing a certain pigment can be spouted by irradiating a light corresponding to an absorption wavelength of the certain pigment, whereby multicolor nanosize ink jets can be formed.

Also, when the plural carbon nanotubes having different structures and sizes are provided and bundled to form a carbon nanotube bundle, only a certain liquid among the plural liquids occluded in the carbon nanotube bundle can be heated above its liquid-gas phase transition temperature based on the difference of absorption wavelengths resulted from the structures and sizes of the carbon nanotubes constituting the carbon nanotube bundle and spouted from the carbon nanotube. Thus, multicolor nanosize ink jets can be also formed in such a constitution.

A kind of the liquid occluded in the carbon nanotube is not particularly limited as far as it can serve as the above-mentioned nanojet mechanism. As matters now stand, the nanojet mechanism is confirmed in water and alcohols such as ethyl alcohol and the like.

Particularly, the inventors have studied the water in detail. When the water is occluded in the carbon nanotube, it is occluded and kept in the form of an ice nanotube occluded at the atomic level in a cavity of the carbon nanotube.

In the ice nanotube, the carbon nanotube or the carbon nanotube bundle is contacted with water. As the water may be used a normal liquid one or a steam. In the latter case, the carbon nanotube or the carbon nanotube bundle can be contacted with the water by, for example, disposing under a saturated steam without using special steam-generating means. In the former case, the carbon nanotube or the carbon nanotube bundle can be contacted with the water by directly immersing in the water.

Thus, when the carbon nanotube or carbon nanotube bundle is contacted with the water, if the operation temperature (environment temperature) is lower than the forming temperature of the ice nanotube (liquid-gas phase transition temperature) depending on the diameter of the carbon nanotube, the water is occluded and supported in the carbon nanotube (in each of the carbon nanotubes constituting the carbon nanotube bundle when the carbon nanotube bundle is used) to constitute a target ice nanotube.

In the above-mentioned operation, any additional pressurizing operation or the like is not required. That is, although there is some case where a certain pressurized atmosphere of about several GPa is required in the normal solid formation, the above-mentioned operation can be conducted under ambient pressure, i.e. a pressure of not more than about 1 atm in the invention.

In the invention, the carbon nanotube or the carbon nanotube bundle may be subjected to a pretreatment before the carbon nanotube or the like is contacted with the water. Concretely, the carbon nanotube or the like is heated under vacuum, whereby molecules occluded in the carbon nanotube may be removed. Thus, the ice nanotube can be simply and surely formed inside the carbon nanotube.

Furthermore, the carbon nanotube may be subjected to an activating treatment for occluding the water by a heat-treatment between 300 and 500° C. in air, an oxidation treatment in hydrogen peroxide or the method combining them.

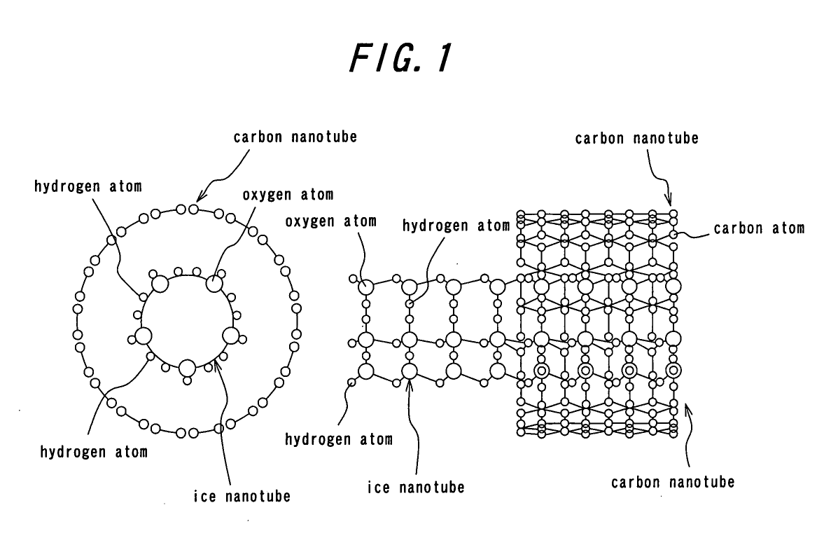

FIG. 1 is a model diagram showing one example of a constitution of the ice nanotube obtained via the above-described steps. As shown in FIG. 1, the ice nanotube according to the invention is kept, for example, in the cavity of the outer carbon nanotube to form 5-member ring composed of oxygen atoms and hydrogen atoms. However, FIG. 1 is illustrative only, and an ice nanotube having 4-member ring to 8-member ring can be formed by controlling the diameter of the carbon nanotube within a range of 1.1 nm to 1.5 nm.

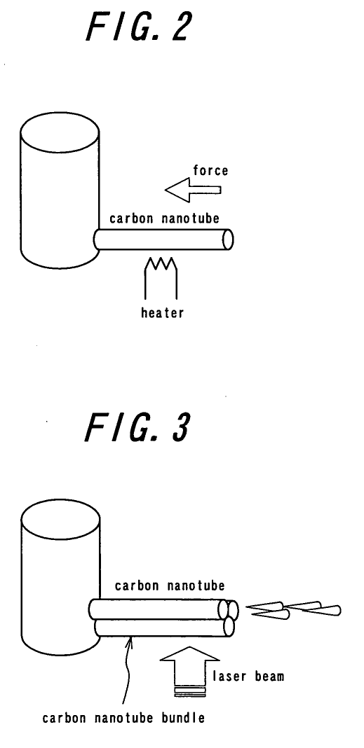

FIG. 2 is a schematic view showing one example of the nanojet mechanism according to the invention and FIG. 3 is a schematic view showing another example of the nanojet mechanism according to the invention. As shown in FIG. 2, when the carbon nanotube is heated by a heater to heat a liquid such as the water or the like occluded therein above the liquid-gas phase transition temperature, the liquid is violently vaporized and spouted from the carbon nanotube. As the spouting form, it can be spouted, for example, as a fine drop in the form of spray or a steam as mentioned above.

On the other hand, when the carbon nanotube bundle is composed of three carbon nanotubes and different liquids are occluded in the respective carbon nanotubes and a laser beam corresponding to an absorption wavelength of at least one liquid among them is irradiated as shown in FIG. 3, only the predetermined liquid is heated above its liquid-gas phase transition temperature and violently vaporized, whereby it is spouted from the corresponding carbon nanotube. Therefore, the spouting the liquid from each of the carbon nanotubes can be controlled independently by irradiating a light having a different absorption wavelength to each liquid occluded in each of the carbon nanotubes constituting the carbon nanotube bundle to heat the liquid.

Also, if the three carbon nanotubes have different structures and/or sizes with each other, the absorption wavelength differs every each carbon nanotube, so that only the liquid occluded in a certain carbon nanotube can be heated above its liquid-gas phase transition temperature and spouted by irradiating a light corresponding to each absorption wavelength.

### EXAMPLES

There are provided six samples of carbon nanotube bundles having an average diameter of 18 nm in which a diameter of each of carbon nanotubes is 1.17 nm, 1.30 nm, 1.34 nm, 1.35 nm, 1.38 nm or 1.44 nm. These samples are heated at 800 K or more under vacuum of 10⁻³ Torr to remove molecules occluded therein. Then, the samples are disposed in a saturated steam of 300 K and charged into a quartz glass container having a thickness of 0.01 mm and then sealed.

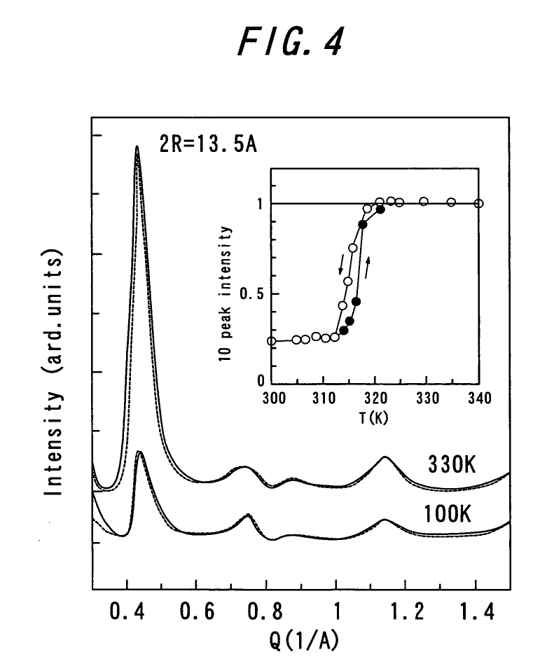

FIG. 4 is XRD patterns of the carbon nanotube bundle composed of the carbon nanotube having an average diameter of 1.35 nm at 100 K and 330 K, respectively. Moreover, an inserted figure is a graph showing a temperature dependency of 10 peaks in the XRD of the sample. As seen from FIG. 4, the 10 peaks rapidly change near about 320 K accompanied with the formation of the ice nanotube by the occlusion of the water into the carbon nanotube and the discharge of steam. On the other hand, since the XRD profile at 330 K is identical to the XRD profile of the carbon nanotube, it is understood that the ice nanotube is formed inside the carbon nanotube below 320 K, while the ice nanotube is vaporized above 320 K and spouted outward as a steam.

Therefore, as seen from FIG. 4, the nanojet mechanism and the nanojet spouting method of the water using the carbon nanotube are established at about 320 K which is a temperature of not less than room temperature.

As a result of the similar analyses for other samples, it is revealed that the ice nanotube is formed inside the carbon nanotube at a temperature of not less than room temperature and the steam is spouted above the liquid-gas phase transition temperature.

Although the invention is described in detail based on the embodiment of the invention with reference to the concrete examples as mentioned above, the invention is not limited to the above content and can be modified and altered without departing from the scope of the invention.

### INDUSTRIAL APPLICABILITY

The nanojet spouting method and the nanojet mechanism according to the invention can be used as an ink jet and as a jet mechanism actuating nano-size parts by utilizing a counteraction produced during the spouting.

1. A nanojet spouting method comprising the steps of:
providing a predetermined carbon nanotube;
occluding a liquid in the carbon nanotube; and
heating the liquid above a liquid-gas phase transition temperature to spout the liquid from the carbon nanotube.

2. A nanojet spouting method according to claim 1, wherein a diameter of the carbon nanotube is 0.7 nm to 3.0 nm.

3. A nanojet spouting method according to claim 1, wherein the occlusion of the liquid is conducted under atmosphere having a pressure of not more than 1 atm.

4. A nanojet spouting method according to claim 1, wherein the liquid is water and the water is occluded as an ice nanotube in the carbon nanotube.

5. A nanojet spouting method according to claim 4, wherein the carbon nanotube is contacted with saturated steam and moisture in the saturated steam is occluded inside the carbon nanotube to make the ice nanotube.

6. A nanojet spouting method according to claim 5, wherein the carbon nanotube is heated under vacuum atmosphere to remove molecules occluded in the carbon nanotube before the carbon nanotube is contacted with the saturated steam.

7. A nanojet spouting method according to claim 4, wherein the ice nanotube constitutes 4-member ring to 8-member ring composed of oxygen atoms and hydrogen atoms.

8. A nanojet spouting method according to claim 1, wherein the liquid-gas phase transition temperature is not less than 0° C.

9. A nanojet spouting method according to claim 1, which comprises the steps of:
providing plural carbon nanotubes;
bundling these plural carbon nanotubes to form a carbon nanotube bundle; and
occluding plural liquids in the carbon nanotube bundle, and heating only a predetermined liquid above its liquid-gas phase transition temperature by irradiating a light corresponding to an absorption wavelength of the predetermined liquid to spout only the predetermined liquid from the carbon nanotube.

10. A nanojet spouting method according to claim 1, which comprises the steps of:
providing plural carbon nanotubes having different structures and sizes, and bundling these plural carbon nanotubes to form a carbon nanotube bundle; and
occluding plural liquids in the carbon nanotube bundle, and heating only a predetermined liquid above its liquid-gas phase transition temperature based on the difference of absorption wavelengths resulted from the structures and sizes of the carbon nanotubes constituting the carbon nanotube bundle to spout only the predetermined liquid from the carbon nanotube.

11. A nanojet mechanism comprising:
a predetermined carbon nanotube; and
a liquid to be occluded in the carbon nanotube and to be spouted from the carbon nanotube by heating above a liquid-gas phase transition temperature.

12. A nanojet mechanism according to claim 11, wherein a diameter of the carbon nanotube is 0.7 nm to 3.0 nm.

13. A nanojet mechanism according to claim 11, wherein the occlusion of the liquid is conducted under atmosphere having a pressure of not more than 1 atm.

14. A nanojet mechanism according to any claim 11, wherein the liquid is water and the water is occluded as an ice nanotube in the carbon nanotube.

15. A nanojet mechanism according to claim 14, wherein the carbon nanotube is contacted with saturated steam and moisture in the saturated steam is occluded inside the carbon nanotube to make the ice nanotube.

16. A nanojet mechanism according to claim 15, wherein the carbon nanotube is heated under vacuum atmosphere to remove molecules occluded in the carbon nanotube before the carbon nanotube is contacted with the saturated steam.

17. A nanojet mechanism according to claim 14, wherein the ice nanotube constitutes 4-member ring to 8-member ring composed of oxygen atoms and hydrogen atoms.

18. A nanojet mechanism according to claim 11, wherein the liquid-gas phase transition temperature is not less than 0° C.

19. A nanojet mechanism according to claim 11, which comprises:
a carbon nanotube bundle having plural carbon nanotubes and being formed by bundling these plural carbon nanotubes; and
a light irradiation source to heat only a predetermined liquid above its liquid-gas phase transition temperature among plural liquids occluded in the carbon nanotube bundle and to spout only the predetermined liquid from the carbon nanotube by irradiating a light corresponding to an absorption wavelength of the predetermined liquid.

20. A nanojet mechanism according to claim 11, which comprises:
a carbon nanotube bundle having plural carbon nanotubes with different structures and sizes and being formed by bundling the plural carbon nanotubes; and
a light irradiation source to heat only a predetermined liquid above its liquid-gas phase transition temperature among plural liquids occluded in the carbon nanotube bundle and to spout only the predetermined liquid from the carbon nanotube based on the difference of absorption wavelengths resulted from the structures and sizes of the carbon nanotubes constituting the carbon nanotube bundle.
